(19) United States
(12) Patent Application Publication
(10) Pub. No.: US 2017/0012195 A1
(43) Pub. Date: Jan. 12, 2017

(54) METHOD FOR MANUFACTURING SEMICONDUCTIVE BRANCHES FOR A THERMOELECTRIC MODULE, AND THERMOELECTRIC MODULE

(71) Applicant: OBSHCHESTVO S OGRANICHENNOY OTVETSTVENNOSTYU "RUSTEC", Moscow (RU)

(72) Inventor: Valeriy Ivanovich GRISHIN, Moscow (RU)

(21) Appl. No.: 15/121,176

(22) PCT Filed: Feb. 24, 2014
(86) PCT No.: PCT/RU2014/000116

§ 371 Date: Aug. 24, 2016

(51) Int. Cl. H01L 35/32; H01L 35/10; H01L 35/34

(52) U.S. Cl. CPC H01L 35/32; H01L 35/34; H01L 35/10

(57) ABSTRACT

The claimed invention can be used for the manufacturing of thermoelectric modules. The method includes the manufacturing of rods from a thermoelectric material by a hot extrusion method. Then, the side surface of the rods is preliminarily treated.

Then, a water-based paint system with fluorine rubber is applied on the side surface of the rods by a cathode or anode electrodeposition method and a protective polymeric coating is produced. Then, the rods are washed and thermally cured. The rods are cut and semiconductor branches of a specified length are produced. After that, an antidiffusion metallic coating is applied on the face surfaces of the produced semiconductor branches so that the edge is in contact with the protective polymeric coating without crossing it. The claimed process enable an improvement in the chemical, thermal, and mechanical resistance and provision of a high adhesion and plasticity of the polymeric coating of the thermoelectric branches.

### CROSS-REFERENCE

The present application is a National Phase Entry of International Patent Application no. PCT/RU2014/000116, filed on Feb. 24, 2014, entitled “METHOD FOR MANUFACTURING SEMICONDUCTIVE BRANCHES FOR A THERMOELECTRIC MODULE, AND THERMOELECTRIC MODULE”. This application is incorporated by reference herein in its entirety.

### FIELD OF THE INVENTION

The claimed group of inventions pertains to thermoelectric devices and can be used for the manufacturing of thermoelectric modules.

### BACKGROUND

A thermoelectric module containing thermoelectric devices with a metal coating applied (WO 2011118341 A1, Sep. 29, 2011) is known. This patent also discloses a method for applying a metal coating on thermoelectric elements.

A thermoelectric module that is disclosed in patent RU 2178221 C2, Jan. 10, 2002, which contains semiconductor branches of N- and P-type conductivity that are located in parallel and are not in contact with each other, the ends of the semiconductor branches being connected through switching buses in an electric circuit so the external sides of the switching buses are connected to heat sinks, can be accepted as a closer analog in terms of the thermoelectric module.

This patent also discloses a method for producing semiconductor branches that consists in the application of a polymeric coating by deposition.

Common disadvantages of the known thermoelectric modules and manufacturing method are as follows:

1) Low reliability of the thermoelectric module due to the high rate of thermal degradation and low resistance to thermal cycling

2) Low chemical, thermal, and mechanical resistance of semiconductor branches during the manufacturing and operation of a thermoelectric module

3) Low adhesion and plasticity of the coating that leads to the coating delamination in temperature cycles.

The task of the claimed group of the invention is to eliminate these disadvantages.

The technical effect of the claimed group of the inventions is the improvement of the reliability of a thermoelectric module due to:

1) Reduction in the rate of thermal degradation and increase in the resistance to thermal cycling;

2) Increase in the resistance of semiconductor branches to the chemical, thermal, and mechanical impacts during the manufacturing and operation of a thermoelectric module;

3) Increase in the adhesion and plasticity of a polymeric coating of thermoelectric branches and elimination of its delamination in temperature cycles.

It is achieved by manufacturing rods in the method for manufacturing of semiconductor branches for a thermoelectric module as per the invention from a thermoelectric material by a hot extrusion method, after which the side surfaces of the rod are prepared; then, a water-based paint system with fluorine rubber is applied on the side surface of the rods by a cathode or anode electrolytic deposition method and a protective polymeric coating is produced; then, the rods are washed and thermally cured and cut to produce semiconductor branches of a specified length, after which an antidiffusion metal coating is applied on the end surfaces of the produced semiconductor branches so that the edge is in contact with the protective polymeric coating without crossing it.

Furthermore, the rods manufactured by a hot extrusion method can have a round or square or rectangular cross-section. Side surfaces of the rods are prepared by degreasing, pickling, etching, and washing them with demineralized water and treating them with solvents. The time of electrolytic deposition of the water-based paint system is 60-120 sec. After the coating application, the rods are washed in demineralized water and thermally cured in a furnace at a temperature of 180-220° C. for 10-30 minutes. The thickness of the polymeric coating of the side surface of the rods is 5-23 μm. The coating of N-type branches differs in color from the coating of P-type branches. The antidiffusion metallic coating is applied on the end faces of the produced semiconductor branches by a combined method using consecutive alternation of galvanic and chemical layers.

The technical effect is also achieved by manufacturing of the N- and P-type semiconductor branches in a single-stage or multistage thermoelectric module as per the invention that contains semiconductor branches of N- and P-type conductivity, which are located in parallel and are not in contact with each other, the end faces of the semiconductor branches being connected through switching buses in an electric circuit so that the external sides of the switching buses are connected to heat sinks, by the above method.

### BRIEF DESCRIPTION OF THE DRAWINGS

The invention is explained in more details with the reference to the enclosed drawings, in which:

FIG. 1 shows the general view of a single-stage (1) and multistage (2) thermoelectric module

FIG. 2 shows a soldered N- and P-type semiconductor branch, completely protected with a polymeric coating throughout the length of the side surface, except for the switching buses and heat sinks

FIG. 3 shows a partially cut-away (detached) thermoelectric module for a detail view

FIG. 4 shows the extruded thermoelectric rods without any protective coating (of round, square, and rectangular cross-section)

FIG. 5 shows the extruded thermoelectric rods with a deposited N-type (black) and P-type (red) polymeric coating

FIG. 6 shows the thermoelectric rods glued onto a table for the next operation (disk or wire machine cutting)

FIG. 7 shows the thermoelectric rods glued onto a table that are cut in thermoelectric branches (elements) by a disk-cutting machine

FIG. 8 shows the thermoelectric branches with the applied coating for soldering in the form of a tin alloy (1) and gold alloy (2)

FIG. 9 shows a thermoelectric module produced by the process of hot extrusion of a thermoelectric material and application of a polymeric coating by the method of electrolytic anode or cathode deposition

FIG. 10 shows a part of a thermoelectric module, in which defects (11) and (12) could impair the performance, if there were no coating

FIG. 11 shows a section of a round thermoelectric branch and a junction point of the polymeric coating (3) and the antidiffusion metallic coating (13).

### DESCRIPTION OF THE EMBODIMENTS

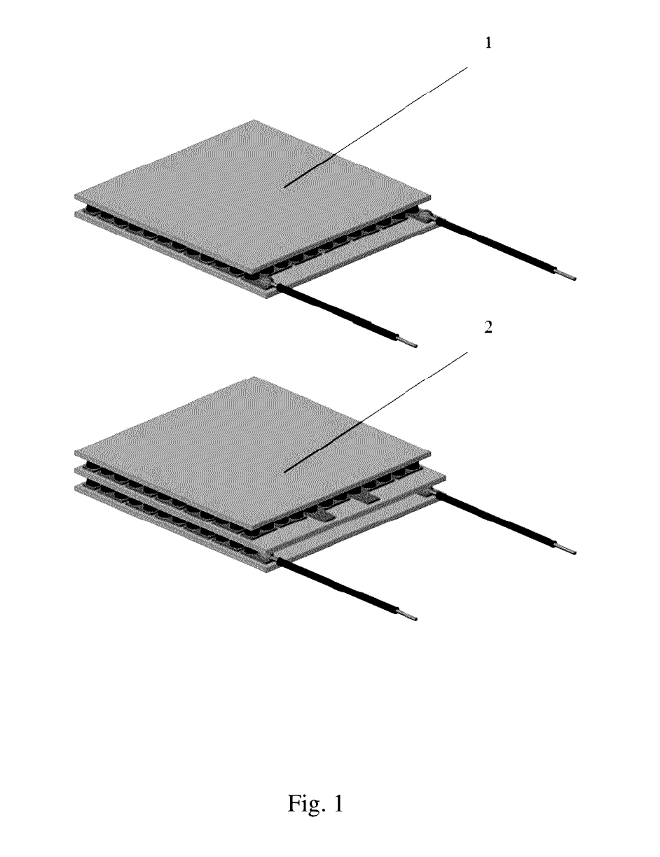

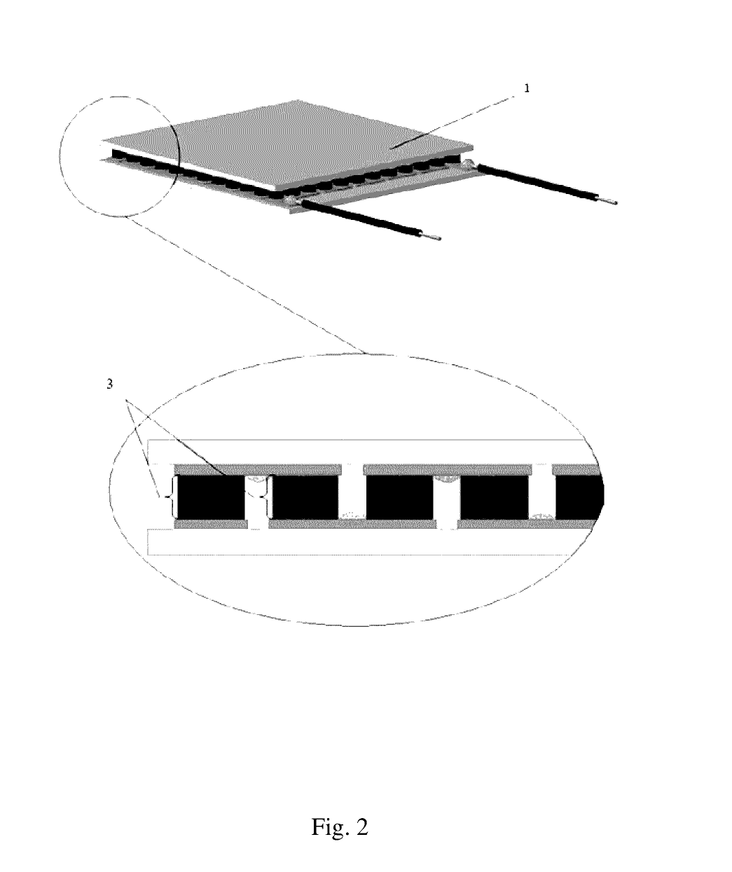

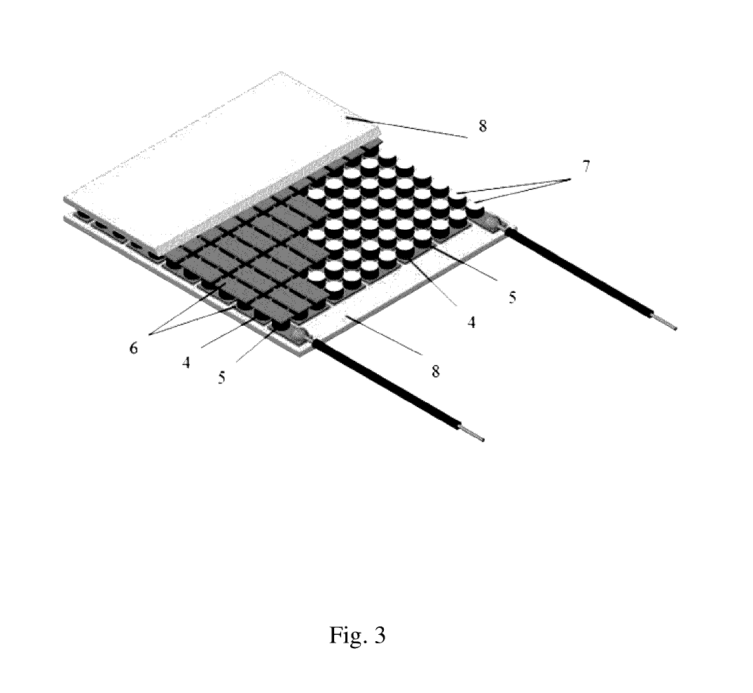

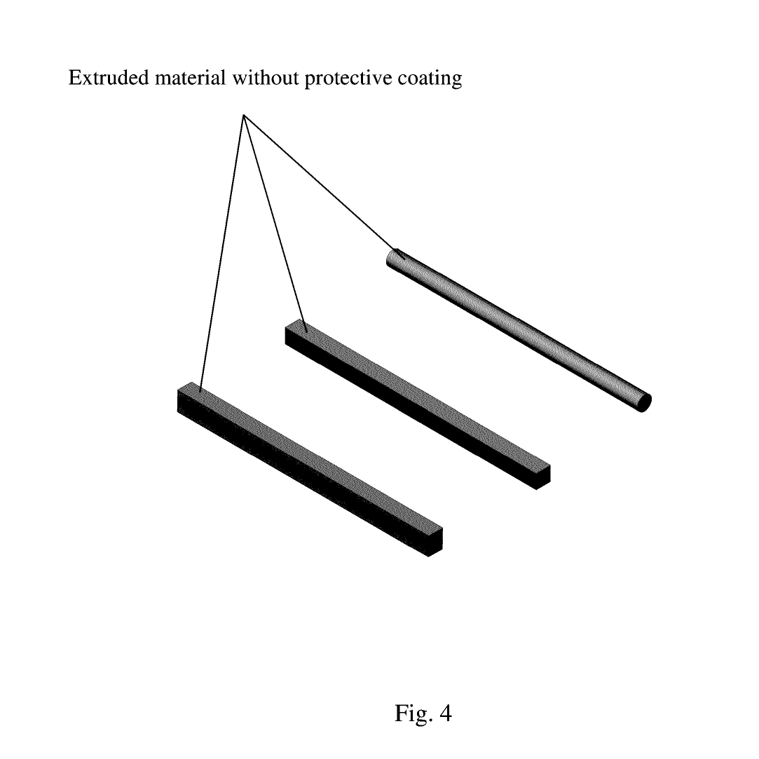

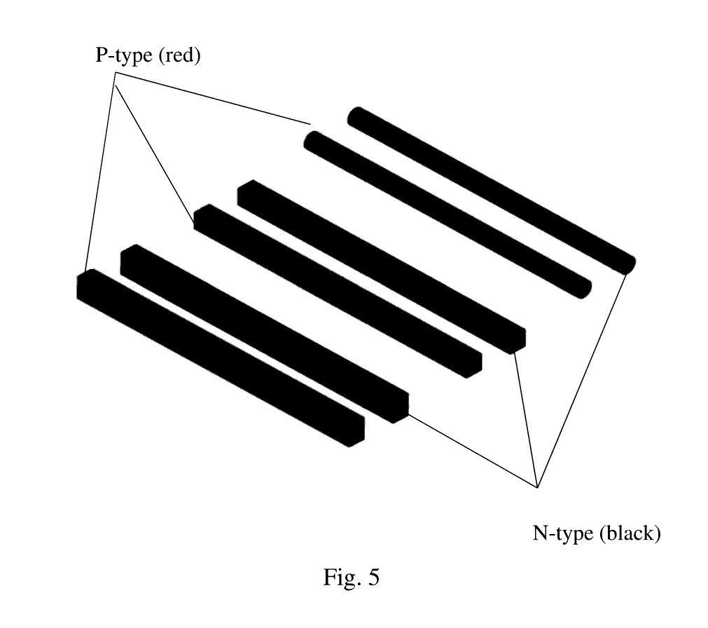

A single-stage (1) or multistage (2) thermoelectric module (FIG. 1) contains extruded semiconductor branches of N- and P-type conductivity. Semiconductor branches can have various cross-sections (round, square, rectangular, etc.). Each N- and P-type semiconductor branch is completely protected (FIG. 2) with a polymeric coating (3) throughout the length of the side surface, except for the end faces of the semiconductor branch, switching buses, and heat sinks. The coating application method is a cathode or anode electrolytic deposition. In a thermoelectric module (FIG. 3), the N-type (4) and P-type (5) semiconductor branches are located in parallel and not in contact with each other, and switching buses (6) connect the end faces (7) of semiconductor branches in an electric circuit. The external sides of the switching buses are connected to the heat sinks (8). Semiconductor branches of N- and P-type conductivity are used in this embodiment of a thermoelectric module. Solid solutions (Bi₂Te₃)_{X} (Sb₂Te₃)_{1-X} and (Bi₂Te₃)_{X} (Sb₂Te₃)_{Y} (Sb₂Se₃)_{1-X-Y} are used as a material of P-type conductivity. Solid solutions (Bi₂Se₃)_{X} (Bi₂Te₃)_{1-X} are used as a material of N-type conductivity. N- and P-type materials are synthesized, crushed, agglomerated, baked, and exposed to a severe plastic deformation by a hot extrusion method for producing blank rods of round, square, rectangular, or other cross-section and various sizes (FIG. 4). For further processing of the produced rod, it must be protected against thermal and chemical impact by applying a polymeric coating (FIG. 5). In order that the adhesion of the coating to the rod is high, the side surface must be degreased, for example, by placing the rods in a mount and immersing in an ultrasonic bath with a low-alkalinity solution at t=55-60° C., τ=3 minutes (depending on the contamination degree); pickled, for example, by placing the rods in a mount and immersing in a bath with diluted hydrochloric acid at t=23-27° C., τ=1-2 minutes; etched, for example, by placing the rod in a mount and immersing in an etching bath with a mixture of acids (hydrofluoric, hydrochloric, acetic, nitric) at t=30-35° C., τ=15 to 20 sec for P-type rods or at t=20-25° C., τ=15 to 25 sec for N-type rods; washed with demineralized water; and treated with solvents, for example, in an ultrasonic bath with isopropyl alcohol (propanol-2) being used most often at t=40-45 ° C., τ=1 minute, or with acetones, aromatic hydrocarbons and the like, or their mixtures. The water-based paint system can be electrodeposited after the side surface of the rod is prepared.

To apply the coating, it is necessary to prepare a water-based paint system and fill it into a bath. The water-based paint system consists (weight %) of demineralized water (52.50%); pigment paste CATHOGUARD 580 PASTE QT 34-9575 (black) by BASF Coating AG (8.70%) or pigment paste of other color (red); epoxy binding emulsion CATHOGUARD 580 BINDER QT 33-0500 by BASF Coating AG (37.81%); and fluorine rubber latex SKF-264V (Technical Specifications TU2294-019-13693708-2004 for fluorine rubber latex SKF-264V) (0.99%). The water-based paint system used can have various colors (FIG. 5). There is high probability when assembling thermoelectric modules that N-type and P-type branches can be mixed up. It is preferable that the coating of N-type branches should differ from P-type in color eliminating thus the possible polarity reversal during the assembly of thermoelectric modules.

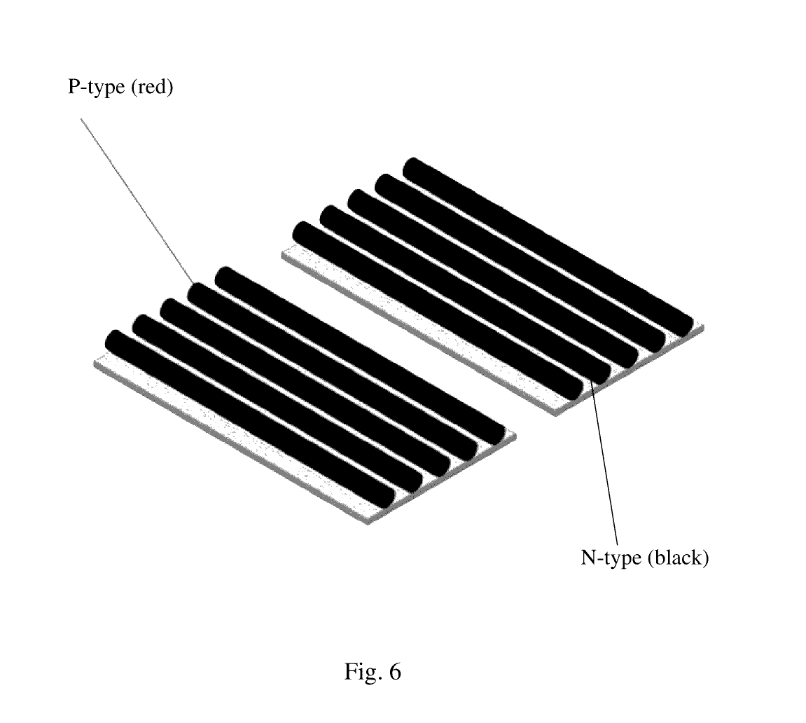

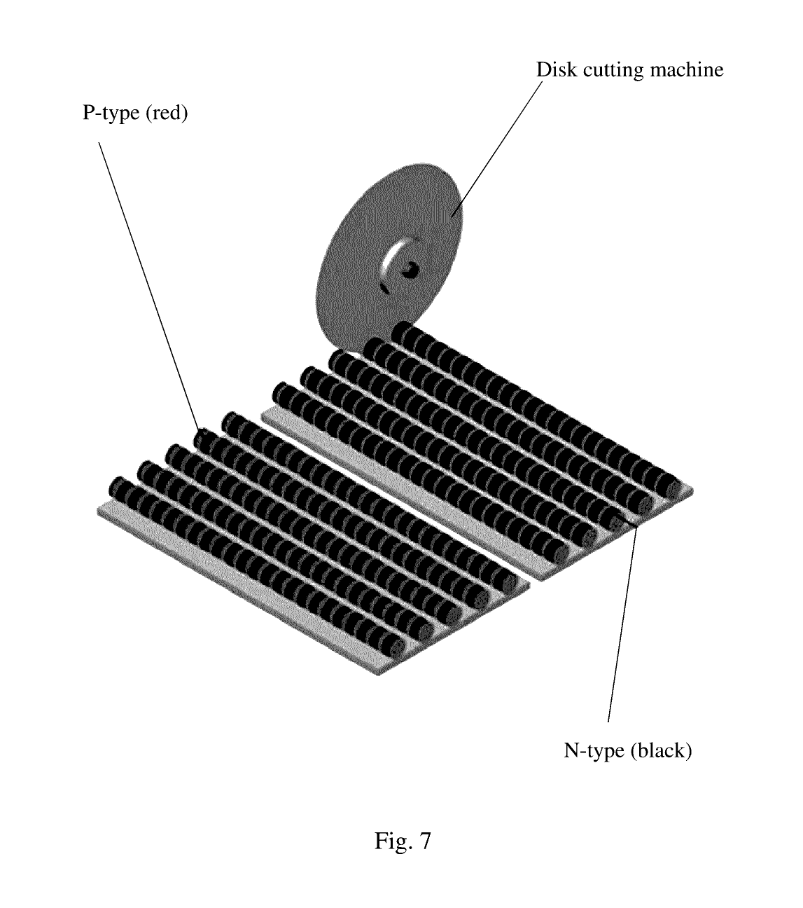

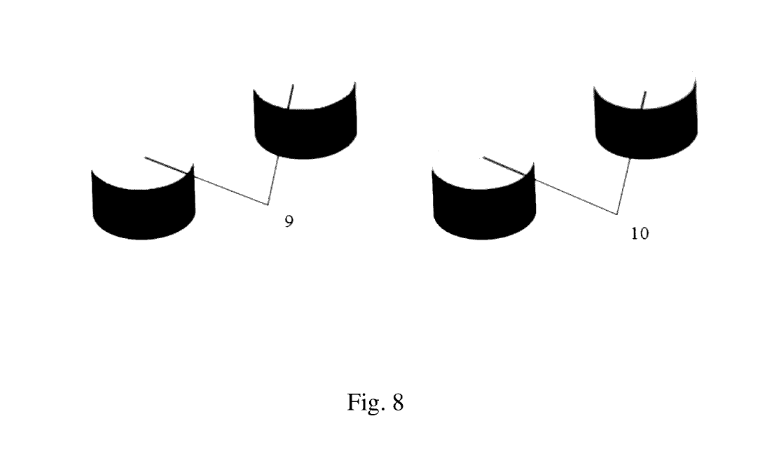

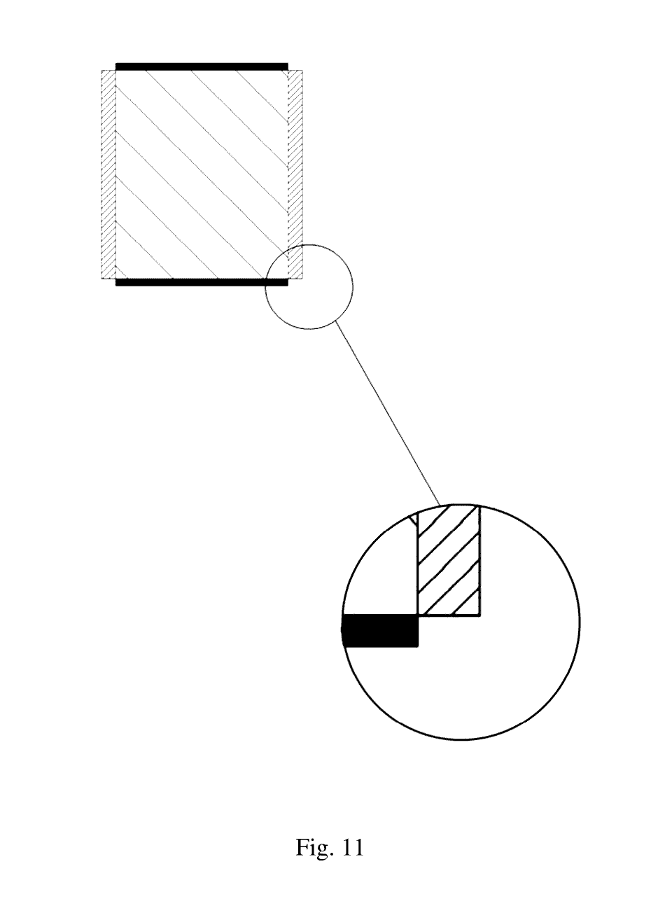

The water-based paint system is electrodeposited by immersing a rod in an electrolytic deposition bath, which is equipped with systems for mixing, filtration, and thermostatting of the treatment solution at T=28-32° C., an electrodialysis cleaning system, and a DC power supply U=160-250 V. The rod that is fixed in a mount is an anode or a cathode, and the plates purposely immersed in the bath are an opposite electrode. The process of the rod coating formation consists in that under the action of the electric current the water-soluble film-forming resin loses its solubility and is deposited on the rod. The rod sections, which are in the zone of a maximum current density, are colored first; then, as the insulating action of the deposited layer is increased, the lines of electric force are redistributed and the deposition area is shifted along the surface of the rod being colored. This results in the formation of a dense but thin insulating coating over the whole surface of the rod. The time of formation of an electrodeposited coating is 60-120 sec. After the coloring of the coating, the rod is washed by dipping in a bath with demineralized water and thermally cured in a furnace at 180-220° C. for 10-30 minutes. The polymeric coating produced by a cathode or anode electrodeposition method has a thickness of 5-23 μm. With the protective layer formed, the rods are sorted by conductivity (by color) and each rod is glued onto its table (FIG. 6). The rods glued onto a table are cut with a disk or wire cutting machine to a size specified for semiconductor branches (FIG. 7); washed in isopropyl alcohol; and dried in a furnace. The produced branches are preliminarily treated for application of an antidiffusion metallic coating on the end faces by the combined method. The combined method includes consecutive alternation of galvanic and chemical layers. A galvanic layer Ni 59-71%, Sn 29-41% with a thickness of 2-3 μm is first applied and then chemical layer Ni 93-97%, P 3-7% with a thickness of 2-3 μm is applied, etc. After the preliminary treatment, the antidiffusion metallic coating is applied. The antidiffusion metallic coating is applied so that the edge is in contact with the protective polymeric coating, without crossing it (FIG. 11, pos. (13), (3)). The reason for it is the subsequent soldering of the branch: the more is the closed area of the soldering, the worse the flux comes out of the soldered spot and hollows and cavities are thus formed and worsen the reliability of the thermoelectric module; and then, a soldering coating (FIG. 8) in the form of a tin (9) or gold (10) alloy is applied. At the end of application of all coatings, the branches are inspected for quality and transferred for assembling a thermoelectric module.

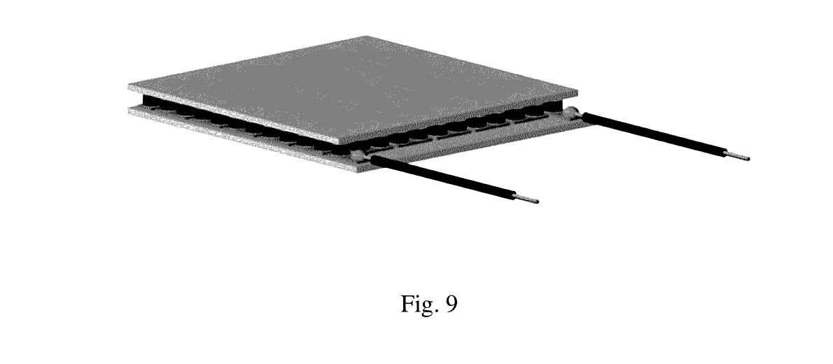

The thermoelectric module (FIG. 9) is assembled using a known method. The operation of the thermoelectric module does not differ from operation of the known thermoelectric modules, for example, specified as analogs. However, the claimed thermoelectric module that is assembled from branches protected with a polymeric coating has the following advantages:

1. Extrusion of the branch ensures saving about 50% of the thermoelectric material that has an impact on the cost of a thermoelectric module. In a standard method for manufacturing branches, about 30 to 50% of the thermoelectric material is wasted.

2. High reliability in thermal cycling, as in the manufacturing of an extruded branch there is no tearing of the antidiffusion metallic coating, as it is applied after mechanical actions. In a standard method for manufacturing branches, there is always a tearing of the antidiffusion metallic coating due to the mechanical action during cutting of the thermoelectric material (plate) with the metallic coating applied, for example, by a diamond disk, wire, etc., more in some cases and less in others. Any tearing impairs the reliability of the thermoelectric module.

3. High reliability in thermal cycling in the manufacturing of round-section branches. There are no angular mechanical stresses as in the branches of other geometrical shapes.

4. The polymeric coating produced by a cathode or anode electrodeposition on branches provides:

a) Protection at a direct contact against chemical and thermal action in the manufacturing of extruded branches. During the application of an antidiffusion metallic coating, the branches are in a liquid, chemically aggressive medium at a high temperature. The polymeric coating makes it possible to withstand all negative factors without problems.

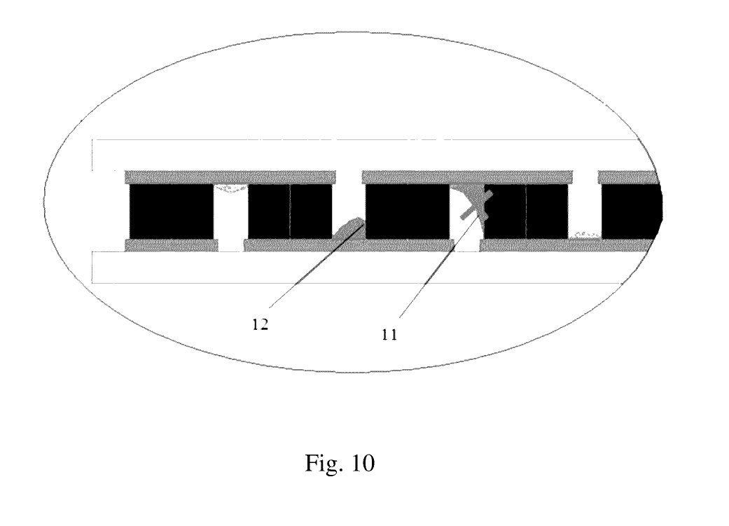

b) Protection of semiconductor branches against side flowing of the flux and solder. During the soldering of semiconductor branches to the buses, the solder can shunt (short-circuit) because of the activity of the flux. The resulting thermal shunt impairs the performance of the thermoelectric module, FIG. 10 (11).

c) Protection of semiconductor branches against diffusion of doping chemical elements from the solder in the thermoelectric material through the side surfaces, FIG. 12). Diffusion of doping chemical elements leads to a change in the properties of the thermoelectric branch that accelerates the failure of the thermoelectric module.

d) Minimal flowing of thermal currents between heat sinks since it has a thickness of 5-23 μm. An increase in the thickness of the polymeric coating has a negative effect on ΔT ° C. of the thermoelectric module. Reduction in the thickness of the polymeric coating decreases the resistance to the aggressive medium. The optimal thickness is 5-23 μm.

e) Resistance to chemical, thermal, and mechanical actions during the operation of the thermoelectric module. The polymeric coating increases the resistance to corrosion and humidity and prevents the destruction of the thermoelectric branch both from mechanical and thermal stresses.

f) High adhesion to thermoelectric branches and plasticity. It enables the polymeric coating not to delaminate from the thermoelectric branch in temperature cycles.

Technical achievements of the claimed group of the inventions consist in the following.

A thermoelectric module assembled from the branches that are produced by the described process has new technical characteristics:

1) Protection of the thermoelectric module against corrosion in a humid environment without encapsulation along the perimeter has increased: for example, continuous operation of the thermoelectric module to failure was more than 18,000 hours at a humidity W=100% and temperature T=25° C.

2) Resistance to thermal degradation has increased: for example, relative resistance variation of thermoelectric module was ΔR≦5% for 1,000 hours at a temperature T=150° C.

3) Thermal cycling reliability has increased: for example, when on the cold heat sink the temperature was cycling using scheme 20° C.→120° C.→20° C. and the temperature of the hot heat sink was 50 ° C., the relative resistance variation of the thermoelectric module was ΔR≦5% after 110,000 cycles.

1. A method for manufacturing semiconductor branches for a thermoelectric module characterized in that the rods are produced from a thermoelectric material by a hot extrusion method, after which the side surface of the rods is preliminarily treated; then, a water-based paint system with fluorine rubber is applied on the side surface of the rods by a cathode or anode electrodeposition method and a protective polymeric coating is produced; then, the rods are washed and thermally cured; then, the rods are cut and P- and N-type semiconductor branches of a specified length are produced, after which an antidiffusion metallic coating is applied on the face surfaces of the produced semiconductor branches so that the edge is in contact with the protective polymeric coating without crossing it.

2. The method of claim 1 characterized in that the rods produced by a hot extrusion method can have a round, or square, or rectangular cross-section.

3. The method of claim 1 characterized in that the side surfaces of the rods are preliminarily treated by degreasing, pickling, etching, washing with demineralized water, and treating them with solvents.

4. The method of claim 1 characterized in that the time of electrodeposition of a water-based paint system is 60-120 sec.

5. The method of claim 1 characterized in that after the application of the coating the rods are washed in demineralized water and thermally cured in a furnace at a temperature of 180-220° C. for 10-30 minutes.

6. The method of claim 1 characterized in that the thickness of the polymeric coating on the side surface of the rods is 5-23 μm.

7. The method of claim 1 characterized in that the coating of N-type branches differs from the coating of P-type branches in color.

8. The method of claim 1 characterized in that the antidiffusion metallic coating is applied on the end faces of the produced semiconductor branches by a combined method of consecutive alternation of galvanic and chemical layers.

9. A single-stage or multistage thermoelectric module containing semiconductor branches of N- and P-type conductivity, which are located in parallel and are not in contact with each other, the end faces of the semiconductor branches being connected through switching buses in an electric circuit so that the external sides of the switching buses are connected to the heat sinks, characterized in that the N- and P-type semiconductor branches are manufactured by the method of claim 1.
